(19) United States
(12) Patent Application Publication
(10) Pub. No.: US 2020/0379525 A1
(43) Pub. Date: Dec. 3, 2020

(54) COMPUTER SYSTEM WITH THERMAL PERFORMANCE MECHANISM AND METHOD OF OPERATION THEREOF

(71) Applicant: CNEX LABS, Inc., San Jose, CA (US)

(72) Inventors: Shanying Luo, Fremont, CA (US); Xiaowei An, San Jose, CA (US)

(21) Appl. No.: 16/427,046

(22) Filed: May 30, 2019

(51) Int. Cl. G06F 1/20; G06F 1/08; H05K 7/20

(52) U.S. Cl. CPC G06F 1/206; H05K 7/20209; G06F 1/08

(57) ABSTRACT

A computer system includes: a storage controller configured to: read a device temperature from a storage device, and calculate a normalized temperature from the device temperature; a processing device, coupled to the storage controller, configured to: access application data, read a composite temperature from the storage controller, and wherein the composite temperature includes the normalized temperature that is higher than the device temperature when a frequency of the processing device is less than FMAX; and an air flow generator, coupled to the processing device, configured to direct a flow of cooling air based on the composite temperature.

### TECHNICAL FIELD

An embodiment of the present invention relates generally to a computer system, and more particularly to a system for enhancing performance while under thermal stress.

### BACKGROUND

Modern computer systems rely on high speed data processing usually provided by non-volatile storage devices, which are also known as a NVMe solid-state disks. In large data processing systems, thermal management can be challenging. Thermal management involves providing large amounts of chilled air to keep the server components in a safe thermal range. Most modern processors can self-limit their operating frequency in times of thermal stress. The balance of cost of cooling and limited performance in the server devices can be difficult to keep stable. There have been a lot of thermal monitoring mechanisms added to servers and peripherals in order to protect them from thermal breakdown, usually at the expense of the performance of the device.

Thus, a need still remains for a computer system with thermal performance mechanism to provide improved performance, data reliability and recovery. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides an apparatus, including a computer system, including: a storage device configured to: read a device temperature from a storage device, and calculate a normalized temperature from the device temperature; a processing device, coupled to the storage controller, configured to: access application data, read a composite temperature from the storage controller, and wherein the composite temperature includes the normalized temperature that is higher than the device temperature when a frequency of the processing device is less than FMAX; and an air flow generator, coupled to the processing device, configured to direct a flow of cooling air based on the composite temperature.

An embodiment of the present invention provides a method including: reading a device temperature from a storage device calculating a normalized temperature for the storage device; providing a composite temperature including the normalized temperature that can be higher than the device temperature when a frequency of a processing device is less than FMAX; and directing a flow of cooling air to the storage device based on the composite temperature.

An embodiment of the present invention provides a non-transitory computer readable medium including: reading a device temperature from a storage device, and calculating a normalized temperature for the storage device; providing a composite temperature including the normalized temperature that can be higher than the device temperature when a frequency of a processing device is less than FMAX; and directing a flow of cooling air to the storage device based on the composite temperature.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is an example of a functional block diagram of a computer system with thermal performance mechanism in an embodiment of the present invention.

FIG. 2 is an example of a functional block diagram of a computer system with thermal performance mechanism in an embodiment.

FIG. 3 is a compound graph depicting frequency and temperature of the computer system over time.

FIG. 4 is a line graph of a normalized temperature reporting by the thermal performance module in an embodiment.

FIG. 5 is a flow chart of a method of operation of the thermal performance module for the calculation and reporting of the normalized temperature of the processing device.

FIG. 6 is a flow chart of a method of operation of a computer system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The term “module” referred to herein can include software, hardware, or a combination thereof in an embodiment of the present invention in accordance with the context in which the term is used. For example, the software can be machine code, firmware, embedded code, and application software. Also for example, the hardware can be circuitry, processor, computer, integrated circuit, integrated circuit cores, a pressure sensor, an inertial sensor, a microelectromechanical system (MEMS), passive devices, or a combination thereof. The term “multi-dimensional” referred to herein can include 2-dimensional, 3-dimensional, or N-dimensional arrays for processing the multi-dimensional data protection mechanism without limitation.

A message can be distributed amongst the non-volatile storage devices that requires each of the non-volatile storage devices to provide a thermal status in the form of a composite temperature. The composite temperature can allow the processor to manage the cooling functions within the computer system, rack, or data center. The greatest threat to the performance and reliability in the computer system is heat. Many methods have been proposed to accommodate operating the computer system in hot environments, but all of them can reduce operational performance in order to handle the heat.

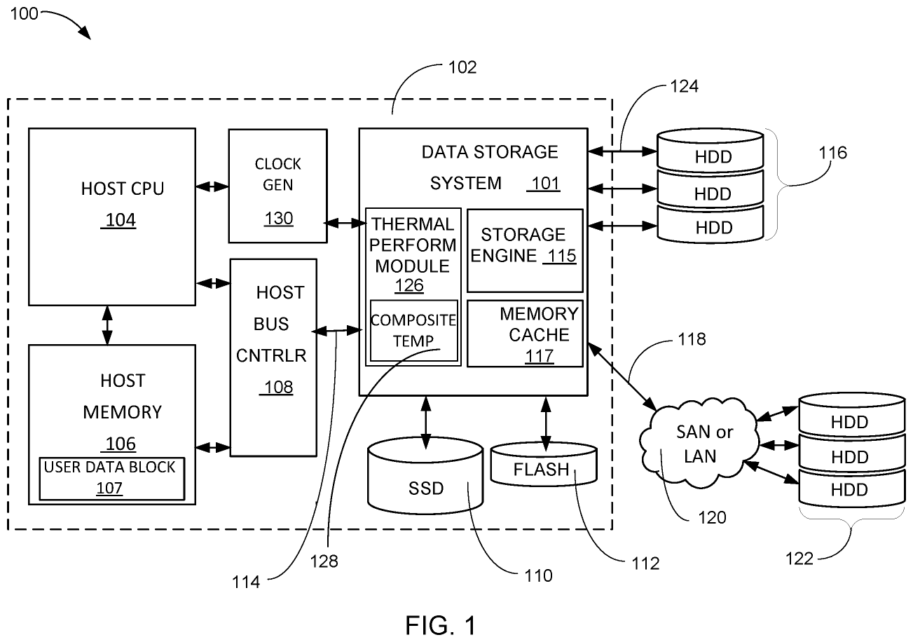

Referring now to FIG. 1, therein is shown a functional block diagram of a computer system 100 with thermal performance mechanism in an embodiment of the present invention. The computer system 100 is depicted in FIG. 1 as a functional block diagram of the computer system 100 with a data storage system 101. The functional block diagram depicts the data storage system 101 installed in a host computer 102.

As an example, the host computer 102 can be as a server or workstation. The host computer 102 can include at least a host central processing unit (CPU) 104, a host memory 106 coupled to the host CPU 104, and a host bus controller 108. The host bus controller 108 provides a host interface bus 114, which allows the host computer 102 to utilize the data storage system 101. The host memory 106 can contain a user data block 107 that can be transferred to or retrieved from the data storage system 101. The host memory 106 can include dynamic random access memory (DRAM), static random access memory (SRAM), a register file, or a combination thereof.

It is understood that the function of the host bus controller 108 can be provided by host CPU 104 in some implementations. The host CPU 104 can be implemented with hardware circuitry in a number of different manners. For example, the host CPU 104 can be a processor, an application specific integrated circuit (ASIC) an embedded processor, a microprocessor, a hardware control logic, a hardware finite state machine (FSM), a digital signal processor (DSP), or a combination thereof. The host bus controller 108 can be a hardware structure that provides support for standard peripheral interface architectures, including but not limited to Serial Advanced Technology Attachment (SATA), the Serial Attached SCSI (SAS), or the Peripheral Component Interconnect-Express (PCI-e).

The data storage system 101 can be coupled to a solid state disk 110, such as a non-volatile memory based storage device having a peripheral interface system, or a non-volatile memory 112, such as an internal memory card for expanded or extended non-volatile system memory.

The data storage system 101 can also be coupled to non-volatile storage devices 116, such as hard disk drives (HDD) or solid state disks (SSD) that can be mounted in the host computer 102, external to the host computer 102, or a combination thereof. The solid state disk 110, the non-volatile memory 112, and the non-volatile storage devices 116 can be considered as direct attached storage (DAS) devices, as an example.

The data storage system 101 can also support a network attach port 118 for coupling a network 120. Examples of the network 120 can be a local area network (LAN) and a storage area network (SAN). The network attach port 118 can provide access to network attached storage (NAS) devices 122.

While the NAS devices 122 are shown as hard disk drives, this is an example only. It is understood that the NAS devices 122 could include magnetic tape storage (not shown), and storage devices similar to the solid state disk 110, the non-volatile memory 112, or the non-volatile storage devices 116 that are accessed through the network attach port 118. Also, the NAS devices 122 can include just a bunch of disks (JBOD) systems or redundant array of intelligent disks (RAID) systems as well as other of the NAS devices 122.

It is understood that the thermal performance mechanism of the present invention can be implemented at the level of the host computer 102, the data storage system 101, the non-volatile storage devices 116, or a combination thereof. The impact of the thermal performance mechanism can benefit the processor-based devices at all levels of the computer system 100.

The data storage system 101 can be attached to the host interface bus 114 for providing access to and interfacing with multiple of the direct attached storage (DAS) devices via a cable 124 for storage interface, such as Serial Advanced Technology Attachment (SATA), the Serial Attached SCSI (SAS), or the Peripheral Component Interconnect-Express (PCI-e) attached storage devices.

The data storage system 101 can include a storage engine 115 and memory devices 117. The storage engine 115 can be implemented with hardware circuitry, software, or a combination thereof in a number of ways. For example, the storage engine 115 can be implemented as a processor, an application specific integrated circuit (ASIC) an embedded processor, a microprocessor, a hardware control logic, a hardware finite state machine (FSM), a digital signal processor (DSP), or a combination thereof. The data storage system 101 can implement the thermal performance mechanism in order to maintain the highest performance possible while operating within the thermal parameters of the devices.

The storage engine 115 can control the flow and management of data to and from the host computer 102, and to and from the direct attached storage (DAS) devices, the NAS devices 122, or a combination thereof. The storage engine 115 can also perform data reliability check and correction, which will be further discussed later. The storage engine 115 can also control and manage the flow of data between the non-volatile storage devices 116 and the NAS devices 122 and amongst themselves. The storage engine 115 can be implemented in hardware circuitry, a processor running software, or a combination thereof.

For example, the data storage system 101 can include a thermal performance module 126. As an example, the thermal performance module 126 can manage communication of a composite temperature 128 to the host CPU 104. The composite temperature 128 is calculated to be the maximum of all of the input temperature submitted to the thermal performance module 126. The thermal performance module 126 is a hardware structure capable of supporting software that can communicate with the solid state disk 110, the non-volatile memory 112, non-volatile storage devices 116 and the NAS devices 122 to request the reporting of the composite temperature 128. The composite temperature 128 provides a status of the thermal condition of the device providing the report. The composite temperature 128 is an indication of the relative temperature of the components in the solid state disk 110, the non-volatile memory 112, non-volatile storage devices 116 or the NAS devices 122.

By way of an example the thermal performance module 126 is shown in the data storage system 101, but it is understood that the thermal performance module 126 can be implemented as part of the host CPU, the solid state disk 110, the non-volatile memory 112, the storage engine 115, non-volatile storage devices 116 or the NAS devices 122. The details of the composite temperature 128 calculation are discussed in other figures.

A clock generator 130 can be coupled to the thermal performance module 126 in order to determine what frequency the host CPU 104 is currently using. The clock generator 130 can be defined as a digital clock synthesizer that can be read to verify the operating frequency and written to alter the frequency provided to the host CPU 104. It is understood that the clock generator 130 can be partitioned as part of the host CPU 104 or part of the data storage system 101 with the same results and capability. For clarity the clock generator 130 is shown as a separate functional block.

For illustrative purposes, the storage engine 115 is shown as part of the data storage system 101, although the storage engine 115 can be implemented and partitioned differently. For example, the storage engine 115 can be implemented as part of in the host computer 102, implemented partially in software and partially implemented in hardware, or a combination thereof. The storage engine 115 can be external to the data storage system 101. As examples, the storage engine 115 can be part of the direct attached storage (DAS) devices described above, the NAS devices 122, or a combination thereof. The functionalities of the storage engine 115 can be distributed as part of the host computer 102, the direct attached storage (DAS) devices, the NAS 122, or a combination thereof.

The storage engine 115 and the memory devices 117 enable the data storage system 101 to meet the performance requirements of data provided by the host computer 102 and store that data in the solid state disk 110, the non-volatile memory 112, the non-volatile storage devices 116, or the NAS devices 122.

For illustrative purposes, the data storage system 101 is shown as part of the host computer 102, although the data storage system 101 can be implemented and partitioned differently. For example, the data storage system 101 can be implemented as a plug-in card in the host computer 102, as part of a chip or chipset in the host computer 102, as partially implement in software and partially implemented in hardware in the host computer 102, or a combination thereof. The data storage system 101 can be external to the host computer 102. As examples, the data storage system 101 can be part of the direct attached storage (DAS) devices described above, the NAS devices 122, or a combination thereof. The data storage system 101 can be distributed as part of the host computer 102, the direct attached storage (DAS) devices, the NAS devices 122, or a combination thereof.

It has been discovered that the inclusion of the thermal performance module 126 at multiple levels of the computer system 100 can enhance performance while maintaining the reliability and thermal integrity of the computer system 100. The thermal performance module 126 can calculate a normalized temperature to be reported as the composite temperature 128. By substituting the normalized temperature for the actual device temperature, the thermal performance module 126 can receive additional portions of cooling air provided to the computing system 100. It is understood that the thermal performance module 126 can be implemented in the host CPU, the solid state disk 110, the non-volatile memory 112, the storage engine 115, non-volatile storage devices 116, the NAS devices 122, or a combination thereof.

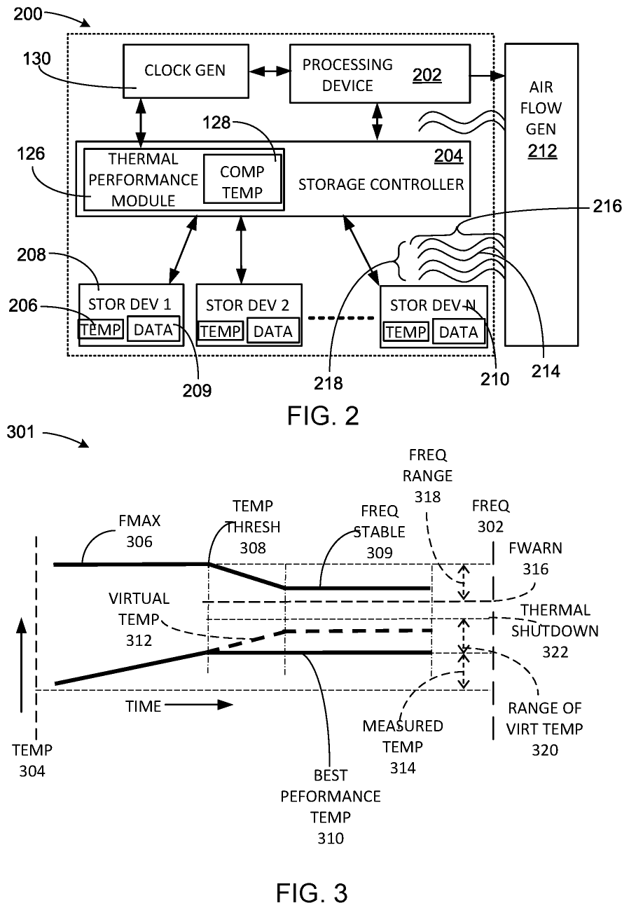

Referring now to FIG. 2, therein is shown a functional block diagram of a computer system 200 with thermal performance mechanism in an alternative embodiment. The functional block diagram of the computer system 200 can be implemented as part of the storage engine 115 of FIG. 1 or the part of the direct attached storage (DAS) devices 116 described above, the NAS devices 122, or a combination thereof. The functional block diagram of the computer system 200 depicts a processing device 202 coupled to a storage controller 204. The processing device 202 can be an application specific integrated circuit (ASIC) an embedded processor, a microprocessor, a hardware control logic, a hardware finite state machine (FSM), a digital signal processor (DSP), or a combination thereof. The storage controller 204 can be a hardware structure capable of executing software to facilitate the transfer of information between the processing device 202 and a storage device 208 coupled to the storage controller 204

As an example, the storage controller 204 can include the thermal performance module 126 configured to receive a device temperature 206 from the storage device 208 coupled to the storage controller 204. The thermal performance module 126 can be configured to read the device temperature 206 from each of the storage device 208 through an Nth storage device 210 and calculate the composite temperature 128. The composite temperature 128 can be transferred to or read by the processing device 202. Each of the storage device 208 through the Nth storage device 210 can store application data 209 that can be accessed by the processing device 202 in high volume. The activities of transferring and storing the application data 209 can increase a temperature 304 of the storage device 208 through the Nth storage device 210. It is understood that the storage device 208 through the Nth storage device 210 can be hard disk drives (HDD), solid state disks (SSD), a Flash memory array, or a combination thereof.

The thermal performance module 126 can be coupled to the clock generator 130 in order to read the current operating frequency or write to the clock generator 130 in order to alter the clock frequency of the processing device 202. It is understood that the clock generator 130 can be implemented as part of the processing device 202 or as part of the storage controller 204 with equal success.

An air flow generator 212 that is coupled to the processing device 202 can be configured to provide cooling air 214 in a flow 216 to the processing device 202, the storage controller 204, the storage device 208 through the Nth storage device 210, or a combination thereof. The air flow generator 212 is controlled by the processing device 202. The processing device 202 can interpret the composite temperature 128 received from the thermal performance module 126 in order to control the air flow generator 212. The air flow generator 212 is a hardware device and can include a fan, chiller, water jacket, directional fins, gates for directing the flow 216, dividing the flow 216 between multiple devices, or a combination thereof.

It has been discovered that the processing device 202 can manage the air flow generator 212 to direct the flow 216 of the cooling air 214 to the devices that are most in need. The processing device 202 can make the cooling decisions based on the composite temperature 128 received from the thermal performance module 126. It is understood that the flow 216 of the cooling air 214 can be directed, by the air flow generator 212, to the processing device 202, the storage controller 204, the storage device 208 through the Nth storage device 210, or a combination thereof as indicated by the composite temperature 128. The processing device 202 can prioritize the cooling of the processing device 202, the storage controller 204, the storage device 208 through the Nth storage device 210, or a combination thereof having a higher value of the composite temperature 128. A higher value of the composite temperature 128 can cause the air flow generator 212 to direct a larger portion 218 of the flow 216 of cooling air 214 to the processing device 202, the storage controller 204, the storage device 208 through the Nth storage device 210, or a combination thereof having the higher value of the composite temperature 128.

Referring now to FIG. 3, therein is shown a compound graph 301 depicting frequency 302 and temperature 304 of the computer system over time in an embodiment. The compound graph 301 shows F_{MAX} 306, such as the maximum frequency that is allowed by the processing device 202 of FIG. 2, such as the HOST CPU 104 of FIG. 1, the data storage system 101 of FIG. 1, the controller of the DAS device 116 of FIG. 1, or the like. While the frequency 302 remains at the F_{MAX} 306 the temperature 304 starts to rise and continues to rise until a temperature threshold 308 is detected within the processing device 202. The processing device 202 can automatically reduce its operating frequency to match the thermal conditions of the environment. In prior devices, the temperature 304 would continue to increase until the device reaches a thermal shutdown threshold 322 and stops processing or the frequency is reduced to a point that poor performance is assured. The thermal performance module 126 can provide a frequency stable region 309 operating at a best performance temperature 310. It is understood that the thermal shutdown threshold 322 is the operating point that marks the thermal level that can produce physical damage to the electronic devices.

The temperature threshold 308 can mark the detection of the best performance temperature 310. The best performance temperature 310 is defined to be the temperature 304 that can support the highest frequency 302 that can be provided when the temperature threshold 308 is detected. It is understood that the processing device 202 would normally continue to increase in temperature 304 even with a reduced operating level of the frequency 302. In order to combat the erosion of the frequency 302 and performance due to the heat, the thermal performance module 126 can report the composite temperature 128 based on a virtual temperature 312 this can be higher than a measured temperature 314. The measured temperature 314 can represent the actual temperature of the storage device 208 of FIG. 2 reporting, while the virtual temperature 312, being hotter than the measured temperature 314, can cause the processing device 202 to direct an increase in the flow 216 of the cooling air 214 from the air flow generator 212 of FIG. 2 to the storage device 208.

It is understood that this approach can be utilized at all levels of the computer system 200, including the storage device 208 through the Nth storage device 210, the storage controller 204, the processing device 202, or a combination thereof. The stable performance of the computer system 200 can be maintained through times of thermal stress based on the thermal performance module 126 managing whether the measured temperature 314 or the virtual temperature 312 is used to calculate the composite temperature 128. The thermal performance module 126 can maintain the frequency stable region 309 between the F_{MAX} 306 and an FWARN 316 in the operational frequency range 318. The virtual temperature 312 can be maintained within a range 320 of the virtual temperature 312. The FWARN 316 is defined as the lowest frequency that can deliver acceptable performance in the computing system 100 or the computing system 200.

It has been discovered that the processing device 202 can configure the air flow generator 212 to deliver a higher volume of the flow of cooling air 214 to the hottest devices based on the reporting of the composite temperature 128 of FIG. 1. By way of an example, in order to maintain the best performance temperature 310 and halt the reduction in the frequency 302, the storage controller 204 can report the virtual temperature 312 instead of the measured temperature 314. The result causes the processing device 202 to configure the air flow generator 212 to increase the flow of cooling air 214 of FIG. 2 directed to the hottest device reporting, such as the storage device 208 through the Nth storage device 210 of FIG. 2. The thermal performance module 126 can maintain the best possible performance by reporting the composite temperature 128 based on the use of the measured temperature 314 or the virtual temperature 312 that can maintain the best performance temperature 310 stable over time.

It is further understood that the thermal performance module 126 can access the clock generator 130 of FIG. 1 to determine the frequency with which the processing device 202 is operating. In instances where the processing device 202 has reduced the frequency 302 too low and caused the temperature 304 to drop below the best performance temperature 310, the thermal performance module 126 can increase the frequency 302 by writing to the clock generator 130. This adjustment can be incremental and does not immediately provide a change in the temperature 304. The monitoring of the frequency 302 can continue as long as the storage device 208 through the Nth storage device 210 are being accessed.

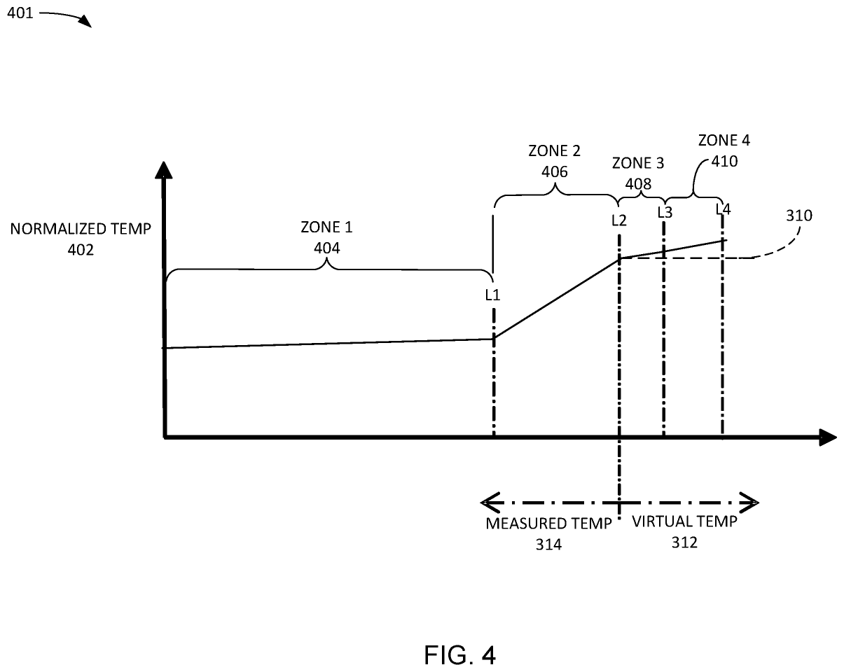

Referring now to FIG. 4, therein is shown a line graph of a normalized temperature reporting 401 by the thermal performance module 126 in an embodiment. In a perfect thermal condition, such as the strong airflow case, the temperature 304 of FIG. 3 of the processing device 202 can stay below the best performance temperature 310 of FIG. 3, the processing device 202 can run at the F_{MAX} 306 to deliver the best performance. If the processing device 202 temperature 304 reaches the best performance temperature 310, the processing device 202 can automatically start self-adjusting the frequency 302 of FIG. 2 to keep the temperature 304 stable at the best performance temperature 310. When the frequency 302 of the processing device 202 is in the frequency stable region 309 of FIG. 3, both the frequency stable region 309 and the best performance temperature 310 will also stay at a balanced stable level. A proportional integral derivative (PID) algorithm (equation 1) is used to keep the best performance temperature 310 at normalized temperature 402 (L2):

### PID Model:

f=Kp*ek+Ki*(ek+ek−1+ek−2)+Kd*(ek−ek−1)+fk equation 1

Equation 1 can be simplified as:

f=K1*ek+K2*ek−1+K3*ek−2+fk equation 2

where:
ek=L2−tk: the delta between the measured temperature 314 and best performance temperature 310
tk: Current controller operating temperature
L2: Controller target (optimal) temperature
fk: Current controller frequency
K1, K2, K3: Parameters. They are tuned based on the system configurations.

It is understood that execution of the PID algorithm can be performed by a combination of hardware and software implemented to monitor the frequency 302 and temperature 304 of the reporting device, such as the HOST CPU 104 of FIG. 1, the data storage system 101 of FIG. 1, the controller of the DAS device 116 of FIG. 1, or the like. By way of an example, equation 2 can be used in the implementation of the storage controller 204 of FIG. 2. This example only uses 3 history temperature errors, which is defined to be the delta between the measured temperature 314 and best performance temperature 310, but there can be any number of the history temperature errors used in the implementation.

The normalized temperature 402 is computed from 4 different zones: In zone 1 404, when the temperature 304 of the processing device 202 is below level 1, there is no need to reduce controller frequency, so it can run the frequency 302 at the F_{MAX} 306 of FIG. 3, which is the highest working value of the frequency 302. In this case, normalized temperature “T” is computed in equation 3.

if t<=L1 and f==Fm

T=t\hat{ }3*Cw/(L3\hat{ }3*Cm)+Cn equation 3

where t is defined to be the temperature 304 recorded by the processing device 202; T is defined as the normalized temperature as calculated for the zone 1 404; C_{W} is defined as a constant value, representing a composite warning temperature level; C_{M} is defined as a constant value, calibrated based on the thermal configuration; C_{N} is defined as a constant value, calibrated based on the thermal configuration; and L3 is defined as a controller virtual temperature at level 3.

In zone 2 406, when the temperature 304 of the processing device 202 is between level 1 and level 2, there is also no need to reduce the frequency 302 of the processing device 202, so the frequency is at the F_{MAX} 306. Which is the highest working value of the frequency 302. In this example, The normalized temperature 402 “T” is computed by equation 4. The slope from the zone 2 406 is higher than the slope of the zone 1 404. In the zone 2 406, the normalized temperature 402 is more sensitive to the temperature change. This zone is usually mapped to the case when controller is working under some busy workload under limited air flow condition.

if L1<t<=L2 and f==Fm

T=t\hat{ }3*C_{w}/(L₃\hat{ }3)+Cₒ equation 4

where t is defined to be the temperature 304 recorded by the processing device 202; T is defined as the normalized temperature as calculated for the zone 2 406; C_{W} is defined as a constant value, represent composite warning temperature level; C₀ is defined as a constant value, calibrated based on the thermal configuration; and L3 is defined as a controller virtual temperature at level 3.

In zone 3 408, the temperature 304 of the processing device 202 will go higher than the temperature 304 detected at L2 if the frequency 302 of the processing device 202 stays at the F_{MAX} 306. To keep the temperature 304 of the processing device 202 stable with the temperature 304 detected at L2, also known as the best performance temperature 310. As long as the frequency 302 can stay between F_{WARN} 316 of FIG. 3 and the F_{MAX} 306, and temperature 304 can remain stable at the best performance temperature 310 detected at L2, we can calculate the virtual temperature (tv) 312 in equation 5, and the normalized temperature 402 in equation 6.

if t==L2 and Fw<=f<Fm

tᵥ=(Fₘ−f)*(L₃−L₂)/(Fₘ−F_{w})+L₂ equation 5

T=tv\hat{ }3*Cw/(L3\hat{ }3)+Co−Co*(Fm−f)/(Fm−Fw) equation 6

Where tv is defined to be the virtual temperature 312 calculated by equation 5; T is defined as the normalized temperature as calculated for the zone 3 408; C_{W} is defined as a constant value, represent composite warning temperature level; C₀ is defined as a constant value, calibrated based on the thermal configuration; and L3 is defined as a controller virtual temperature at level 3; F_{MAX} is defined to be the maximum frequency with which the processing device 202 can operate; F_{WARN} is defined to be a lower value of the frequency 302 that provides unacceptable performance; and f is defined to be the actual frequency applied to the processing device 202.

In zone 4 410, in order to maintain the best performance temperature 310 that was established at L2, if the frequency 302 of the processing device 202 remains stable below F_{WARN} 316, we can calculate the virtual temperature tv 312 in question 7, and the normalized temperature 402 in question 8.

if t==L2 and f<Fw

tv=(Fw−f)*(L4−L3)/(Fw−Fc)+L3 equation 7

T=(tv−L3)*(Cc−Cw)/(L4−L3)+Cw equation 8

Where tv is defined to be the virtual temperature 312 calculated by equation 7; T is defined as the normalized temperature 402 as calculated for the zone 4 410; C_{W} is defined as a constant value, represent composite warning temperature level; C_{C} is defined as a constant value, represent composite critical temperature level; and L3 is defined as a controller virtual temperature at level 3; L4 is defined to be the virtual temperature calculated for L4; F_{C} is defined to be the frequency 302 that is critical to the processing device 202 in order to maintain operation; F_{WARN} is defined to be a lower value of the frequency 302 that provides unacceptable performance; and f is defined to be the actual value of the frequency 302 applied to the processing device 202.

It has been discovered that the calculation of the normalized temperature 402 can adjust the composite temperature 128 of FIG. 1 in order to apply sufficient cooling resource from the air flow generator 212 of FIG. 2 to maintain the best performance temperature 310 and the frequency stable region 309 for an extended operational period. By maintaining the best performance temperature 310 the processing device 202 can maintain a higher performance level than previously possible. The manipulation of the composite temperature 128 by the inclusion of the virtual temperature 312 can provide additional cooling resources from the air flow generator 212 that allow the processing device 202 to operate at the higher level of the frequency 302 for a longer period of time than was previously possible. It is understood that the thermal performance module 126 can read the current operating level of the frequency 302 through the clock generator 130. The thermal performance module 126 can write to the clock generator 130 in order to adjust the frequency 302 based on tracking the best performance temperature 310.

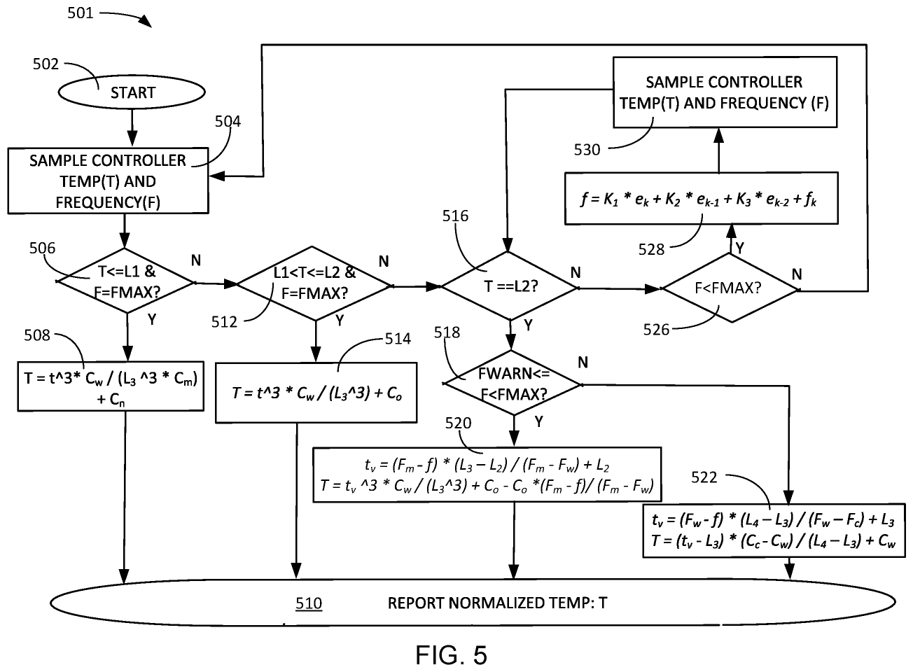

Referring now to FIG. 5, therein is shown a flow chart of a method of operation 501 of the thermal performance module 126 for the calculation and reporting of the normalized temperature 402 of FIG. 4 of the processing device 202 of FIG. 2. The flow chart of the method of operation 501 of the thermal performance module 126 depicts a start block 502 that can initiate the flow. The flow proceeds unconditionally to a sample controller temperature and frequency block 504, in which the measured temperature 314 and the frequency 302 can be captured in a timed sample for future calculations.

The flow proceeds to a check for T<=L1 and F==F_{MAX} in a block 506. The values of the measured temperature 314 and the frequency 302 captured in the sample controller temperature and frequency block 504 can be compared to the temperature 304 captured at L1 of FIG. 4. Since the temperature 304 has not yet reached the best performance temperature 310, the temperature 304 will allow the processing device 202 to operate at the F_{MAX} 306 without requiring additional cooling to maintain the operation at a highest performance point. If the condition is met and T<=L1 and F==F_{MAX} is true, the flow proceeds to a first calculation block 508 where the normalized temperature 402 can be calculated by equation 3 listed above. The flow then proceeds to a report normalized temperature block 510, in which the normalized temperature 402 can be provided as the composite temperature 128 of FIG. 1.

If the condition of the block 506 is not met and T<=L1 and F==F_{MAX} is not true, the flow proceeds to a check for L1<T<=L2 and F==F_{MAX} in a block 512. If the condition is met and L1<T<=L2 and F==F_{MAX} is true, the flow proceeds to a second calculation block 514 where the normalized temperature 402 can be calculated by equation 4 listed above. It is understood that when the temperature 304 has not yet reached the best performance temperature 310, the processing device 202 can continue to operate at the F_{MAX} 306 in order to deliver the best performance. The flow then proceeds to the report normalized temperature block 510, in which the normalized temperature 402 can be provided as the composite temperature 128 of FIG. 1.

If the condition of the block 512 is not met and L1<T<=L2 and F==F_{MAX} is not true, the flow proceeds to a check for T==L2 in a block 516. If the condition is met and T is identically equal to L2, the flow proceeds to a check for F_{WARN}<=F<F_{MAX} in a block 518 to determine whether the frequency 302 is within the frequency range 318 of FIG. 3. If the condition is met and the frequency 302 is within the frequency range 318, the flow proceeds to a third calculation block 520 where the normalized temperature 402 can be calculated by equations 5 and 6 shown above. The flow then proceeds to the report normalized temperature block 510, in which the normalized temperature 402 can be provided as the composite temperature 128.

If the condition of the check for F_{WARN}<=F<F_{MAX} in the block 518 is not met, the flow proceeds to a fourth calculation block 522, where the normalized temperature 402 can be calculated by equations 7 and 8 shown above. The flow then proceeds to the report normalized temperature block 510, in which the normalized temperature 402 can be provided as the composite temperature 128. It is understood that the submission of the normalized temperature 402 for the composite temperature 128 can provide the mechanism to deliver a higher volume of the flow of cooling air 214 of FIG. 2 from the air flow generator 212 that allows the processing device 202 to operate with the frequency 302 and the temperature 304 that provides the best performance possible at the current thermal condition.

In the check for T==L2 in the block 516, if the condition is not met, the flow proceeds to a check for F<F_{MAX} in a block 526. If the frequency 302 of the processing device 202 is less than the F_{MAX} 306 and the temperature 304 is not at the L2 level, the frequency 302 of the processing device 202 must be adjusted in order to maintain the stable condition for the frequency stable region 309 and the best performance temperature 310. In order to facilitate this adjustment, when the frequency 302 is less than the F_{MAX} 306, the flow proceeds to a fifth calculation block 528 in order to use equation 2 listed above to calculate an adjustment to the frequency 302 of the processing device 202. This adjustment, made through the clock generator 130 of FIG. 1, can raise or lower the frequency 302 of the processing device 202 in order to maintain the best performance temperature 310. After the adjustment to the frequency 302, the flow proceeds to a sample controller temperature and frequency block 530 to read the temperature 304 and the frequency 302 of the processing device. Once the new values for the frequency 302 and the temperature 304 are acquired the flow returns to the check for T==L2 in the block 516. This sequence of events can actively control the frequency 302 of the processing device 202 until the best performance temperature 310 is achieved at L2 of FIG. 3, If the check for F<F_{MAX} in the block 526 determines that the frequency 302 is not less than the F_{MAX} 306, the flow proceeds to the sample controller temperature and frequency block 504 to continue the method of operation 501 of the thermal performance module 126.

It has been discovered that the method of operation 501 of the thermal performance module 126 can maintain the highest value of the frequency 302 that will maintain the best performance temperature 310 by reporting the normalized temperature 402 as the composite temperature 128. The normalized temperature 402 can report the normalized temperature 402 that is actually higher than the device temperature 206 of FIG. 2 measured when the processing device 202 is operating at less than the F_{MAX} 306. In order to have the processing device 202 configure the air flow generator 212 to provide additional cooling volume to the storage device 208 of FIG. 2, the thermal performance module 126 can include the normalized temperature 402 rather than the device temperature 206 in the composite temperature 128. It is understood that the processing device 202 can configure the air flow generator 212 to specifically cool any of the storage device 208 through the Nth storage device 210 of FIG. 2, the storage controller 204 of FIG. 2, the processing device 202, or a combination thereof.

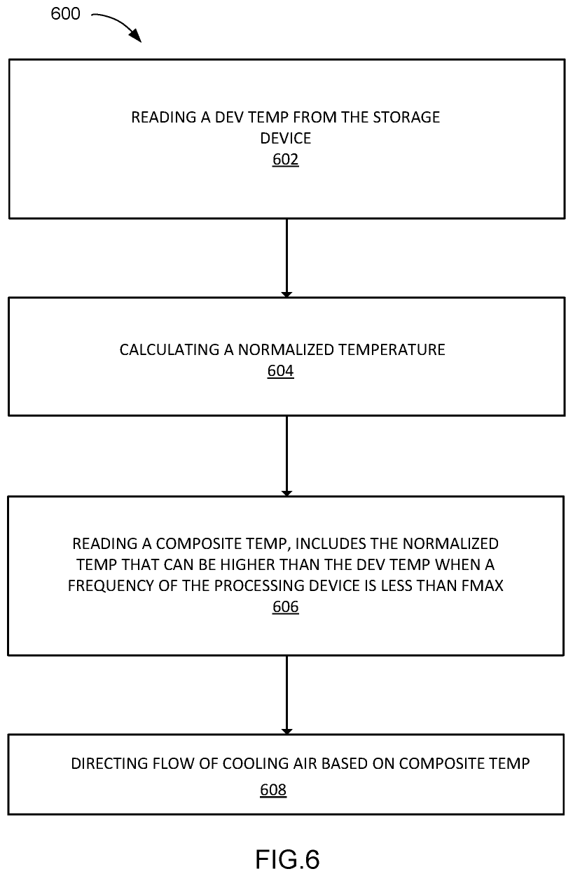

Referring now to FIG. 6, therein is shown a flow chart of a method 600 of operation of a computer system 100 in an embodiment of the present invention. The method 600 includes: reading a device temperature from a storage device in a block 602; calculating a normalized temperature for the storage device in a block 604; providing a composite temperature including the normalized temperature that can be higher than the device temperature when a frequency of a processing device is less than FMAX in a block 606 and directing a flow of cooling air to the storage device based on the composite temperature in a block 608.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A computer system comprising:
a storage controller configured to:
read a device temperature from a storage device, and
calculate a normalized temperature from the device temperature;
a processing device, coupled to the storage controller, configured to:
access application data,
read a composite temperature from the storage controller, and
wherein the composite temperature includes the normalized temperature that is higher than the device temperature when a frequency of the processing device is less than F_{MAX}; and
an air flow generator, coupled to the processing device, configured to direct a flow of cooling air based on the composite temperature.

2. The system as claimed in claim 1 wherein the air flow generator is further configured to provide a portion of the flow of the cooling air to the storage device, the storage controller, the processing device, or the combination thereof based on the composite temperature having a higher value.

3. The system as claimed in claim 1 wherein the storage device configured to calculate the normalized temperature includes reading the device temperature and the frequency of the processing device when the frequency is less than the F_{MAX}.

4. The system as claimed in claim 1 wherein the storage controller is further configured to detect a temperature threshold includes calculating the normalized temperature based on the frequency of the processing device to provide a portion of the flow of cooling air to maintain a frequency stable region.

5. The system as claimed in claim 1 further comprising a clock generator, coupled to the storage controller, configured to allow the storage controller to read the frequency and adjust the frequency by writing to the clock generator.

6. The system as claimed in claim 1 wherein the processing device is configured to automatically reduce the frequency when a temperature is greater than or equal to a best performance temperature.

7. The system as claimed in claim 1 wherein the storage controller is further configured to:
read the frequency from a clock generator;
calculate the normalized temperature; and
adjust the frequency to maintain the best performance temperature.

8. A method of operation of a computer system comprising:
reading a device temperature from a storage device;
calculating a normalized temperature for the storage device;
providing a composite temperature including the normalized temperature that can be higher than the device temperature when a frequency of a processing device is less than F_{MAX}; and
directing a flow of cooling air to the storage device based on the composite temperature.

9. The method as claimed in claim 8 further comprising providing a portion of the flow of the cooling air to the storage device, the storage controller, the processing device, or the combination thereof based on the composite temperature having a higher value.

10. The method as claimed in claim 8 wherein calculating the normalized temperature includes reading the device temperature and the frequency of the processing device when the frequency is less than the FMAX.

11. The method as claimed in claim 8 further comprising detecting a temperature threshold includes calculating the normalized temperature based on the frequency of the processing device to provide a portion of the flow of cooling air to maintain A frequency stable region.

12. The method as claimed in claim 8 further comprising reading from a frequency from a clock generator and adjust the frequency by writing to the clock generator.

13. The method as claimed in claim 8 further comprising automatically reducing the frequency, by the processing device when the temperature is greater than or equal to a best performance temperature.

14. The method as claimed in claim 8 further comprising:
reading the frequency from a clock generator;
calculating the normalized temperature based on the frequency; and
adjusting the frequency to maintain the best performance temperature includes writing to the clock generator.

15. A non-transitory computer readable medium including instructions executable by a computer system, the instructions comprising:
reading a device temperature from a storage device;
calculating a normalized temperature for the storage device;
providing a composite temperature including the normalized temperature that can be higher than the device temperature when a frequency of a processing device is less than FMAX; and
directing a flow of cooling air to the storage device based on the composite temperature.

16. The medium as claimed in claim 15 further comprising providing a portion of the flow of the cooling air to the storage device, the storage controller, the processing device, or the combination thereof based on the composite temperature having a higher value.

17. The medium as claimed in claim 15 wherein calculating the normalized temperature includes reading the device temperature and the frequency of the processing device when the frequency is less than the FMAX.

18. The medium as claimed in claim 15 further comprising detecting a temperature threshold includes calculating the normalized temperature based on the frequency of the processing device to provide a portion of the flow of cooling air to maintain A frequency stable region.

19. The medium as claimed in claim 15 further comprising reading the frequency from a clock generator and adjust the frequency by writing to a clock generator.

20. The medium as claimed in claim 15 further comprising automatically reducing the frequency, by the processing device when the temperature is greater than or equal to a best performance temperature.
